(19) United States
(12) Patent Application Publication
(10) Pub. No.: US 2004/0140002 A1
(43) Pub. Date: Jul. 22, 2004

(54) Apparatus, system, and method of mechanically coupling photovoltaic modules

(76) Inventors: Jacob E. Brown, Corona del Mar, CA (US); Teodor M. Galitev, Fountain Valley, CA (US)

Correspondence Address: MORGAN LEWIS & BOCKIUS LLP, 1111 PENNSYLVANIA AVENUE NW, WASHINGTON, DC, 20004, US

(21) Appl. No.: 10/612,890

(22) Filed: Jul. 7, 2003

Related U.S. Application Data
(60) Provisional application No. 60/393,379, filed on Jul. 5, 2002.

(51) Int. Cl. H01L 25/00

(52) U.S. Cl. 136/251

(57) ABSTRACT

An apparatus, system, and method of mounting a photovoltaic module on a structure. The system includes a first element that is mounted on a structure and a first clamp that engages the first element and that secures the photovoltaic module with respect to the structure. The first clamp includes a body that is adapted to be positioned with respect to the photovoltaic module, and a jaw that pivots about a pivot axis between first and second configurations relative to the body. The first configuration permits non-coaxial displacement with respect to the pivot axis by the first clamp relative to the first element, and the second configuration generally prevents non-coaxial displacement with respect to the pivot axis by the first clamp relative to the first element. The jaw includes a handling end that is operated from above the photovoltaic module, and an operating end that cooperates with the first element.

### CROSS-REFERENCE TO RELATED APPLICATIONS

This application claims the benefit of the earlier filing date of U.S. Provisional Application No. 60/393,379, filed 5 Jul. 2002, the entirety of which is incorporated by reference herein.

### FIELD OF THE INVENTION

Systems for converting solar energy to electrical energy often include a set of photovoltaic cells, a.k.a. “solar cells,” which are mounted on a common base and are electrically interconnected. Such a set of cells can be referred to as a photovoltaic module. It is frequently the case that pluralities of these modules are used together to obtain a desired electrical output, i.e., a specified voltage and current. Inasmuch as these modules are often mounted on top of buildings, it is desirable to provide convenient apparatuses, systems, and methods to install and service the modules.

### BACKGROUND OF THE INVENTION

It is believed that known systems of photovoltaic modules suffer from a number of disadvantages, including requiring a trained technician to fabricate custom assemblies to accommodate the various mounting fixtures on the backside of the known photovoltaic modules. The assemblies must be precisely aligned with the fixtures, which is believed to be very difficult and time consuming in as much as this takes place on the backside a large photovoltaic module, and frequently require specialized tools and parts that must be manipulated while the technician is precariously balanced on a sloping building roof. Another disadvantage of known systems is that the photovoltaic module must be temporarily located, then the electrical connections can be made on the backside of the photovoltaic module, and finally the photovoltaic module can be mounted in its final location. Yet another disadvantage of known systems is that the relative placement of photovoltaic modules is limited by constraints on the availability and access to junction boxes for making electrical connections.

It is believed that there is a need to overcome the disadvantages of the known systems of photovoltaic modules.

### SUMMARY OF THE INVENTION

According to the present invention, a photovoltaic module can be installed or removed without tools. The phrases “without tools” and “manual attachment” refer to a technician performing a task without the use of any hand tools or power tools. Thus, it is possible according to the present invention to simplify and speed up the installation, removal, and replacement of photovoltaic modules, and thereby reduce the amount of time on the top or sides of a structure, e.g., a building, while performing these tasks.

The present invention provides a system of mounting a photovoltaic module on a structure. The photovoltaic module includes at least one photovoltaic cell that converts solar energy to electricity, and includes a first module face that receives the solar energy and a second module face that generally confronts the structure. The system includes a first element that is mounted with respect to the structure and a first clamp that engages the first element and is adapted to secure the photovoltaic module with respect to the structure. The first clamp includes a body that is adapted to be positioned with respect to the photovoltaic module, and a jaw that pivots about a pivot axis between first and second configurations relative to the body. The first configuration permits non-coaxial displacement with respect to the pivot axis by the first clamp relative to the first element, and the second configuration generally prevents non-coaxial displacement with respect to the pivot axis by the first clamp relative to the first element. The jaw includes a handling end that is operated from the first module face of the photovoltaic module, and an operating end that cooperates with the first element.

The present invention also provides an apparatus for mounting a photovoltaic module on a tube. The photovoltaic module includes at least one photovoltaic cell that converts solar energy to electricity, and includes a first module face that receives the solar energy and a second module face that gene rally confronts the structure. The apparatus includes a body that is positioned with respect to the photovoltaic module, and a jaw that pivots about a pivot axis between first and second configurations relative to the body. The first configuration permits non-coaxial displacement with respect to the pivot axis by the first clamp relative to the tube, and the second configuration generally prevents non-coaxial displacement with respect to the pivot axis by the first clamp relative to the tube. The jaw includes a handling end that is operated from the first module face of the photovoltaic module, and an operating end that cooperates with the tube.

The present invention also provides an apparatus for interconnecting a photovoltaic module. The photovoltaic module includes at least one photovoltaic cell that converts solar energy to electricity, and includes a first module face that receives the solar energy, a second module face that generally confronts the structure, and an edge that extends between the first and second module faces. The apparatus includes a wire raceway that extends along an axis and is secured to the edge of the photovoltaic module, a cap that extends along the axis, an attachment plate that partially occludes an axial end of the wire raceway, and at least three wires that extend generally along the axis and that is electrically interconnect the photovoltaic module. The wire raceway includes a generally C-shaped cross-section orthogonal to the axis and includes an opening that extends parallel to the axis. The cap is engageable with the wire raceway to close the C-shaped cross-section. A first arrangement of the cap with respect to the wire raceway provides access through the opening and a second arrangement of the cap with respect to the wire raceway occludes the opening. The attachment plate provides a mechanical coupling to a wiring conduit. And the wires are shielded in the second arrangement of the cap with respect to the wire raceway.

The present invention also provides a photovoltaic module for mounting on a structure via a mounting element. The photovoltaic module includes first and second module faces and an edge that extends between the first and second module faces, a plurality of photovoltaic cells being commonly supported by a base, a manual attachment, a junction box, and a wire raceway. The first module face receives solar energy and the second module face generally confronts the structure. Each of the photovoltaic cells converts the solar energy to electricity. The manual attachment releasably secures the base with respect to the mounting element, the junction box is supported on the base and shields the electrical couplings to the plurality of photovoltaic cells, and the wire raceway extends from the junction box along the edge.

The present invention also provides a method of mounting a mounting a photovoltaic module on a structure. The photovoltaic module includes at least one photovoltaic cell that converts solar energy to electricity, and includes a first module face that receives the solar energy, a second module face that generally confronts the structure, and an edge that extends between the first and second module faces. The method includes positioning the photovoltaic module with respect to the support structure, and securing without tools the photovoltaic module to the support structure.

### BRIEF DESCRIPTION OF THE DRAWINGS

The accompanying drawings, which are incorporated herein and constitute part of this specification, illustrate presently preferred embodiments of the invention, and, together with the general description given above and the detailed description given below, serve to explain features of the invention.

FIG. 1 is a perspective view of a photovoltaic module according to a preferred embodiment of the present invention.

FIG. 2 illustrates an array of four photovoltaic modules according to a preferred embodiment of the present invention.

FIG. 3 is a partial detail view illustrating a preferred manner of attaching a photovoltaic module to a roof structure.

FIG. 4 is a side view showing the preferred manner illustrated in FIG. 3 of attaching the photovoltaic module to the roof structure.

FIG. 5 is a side view of a clamp according to a preferred embodiment of the present invention.

FIG. 6 is a side view of fixed positioning system for the clamp illustrated in FIG. 5.

FIG. 6A is a cross-section view taken along line 6A-6A in FIG. 6.

FIG. 7 is a side view of variable positioning system for the clamp illustrated in FIG. 5.

FIG. 7A is a cross-section view taken along line 7A-7A in FIG. 7.

FIG. 8 is a schematic view of a “C-shaped” chase according to a preferred embodiment of the present invention.

FIG. 9 is a detail view of an end portion of the “C-shaped” chase illustrated in FIG. 8.

### DESCRIPTION OF PREFERRED EMBODIMENTS

According to preferred embodiments of the present invention, a photovoltaic panel including clamp and wire raceway systems may be installed, or subsequently removed and replaced, without tools and with a minimum of time spent at the installation site, which is frequently at altitude on the top or sides of a building. Thus, each photovoltaic panel according to the present invention can be individually clamped on a support system without being mechanically coupled directly to adjacent photovoltaic panels, which are themselves individually and independently clamped to the support system.

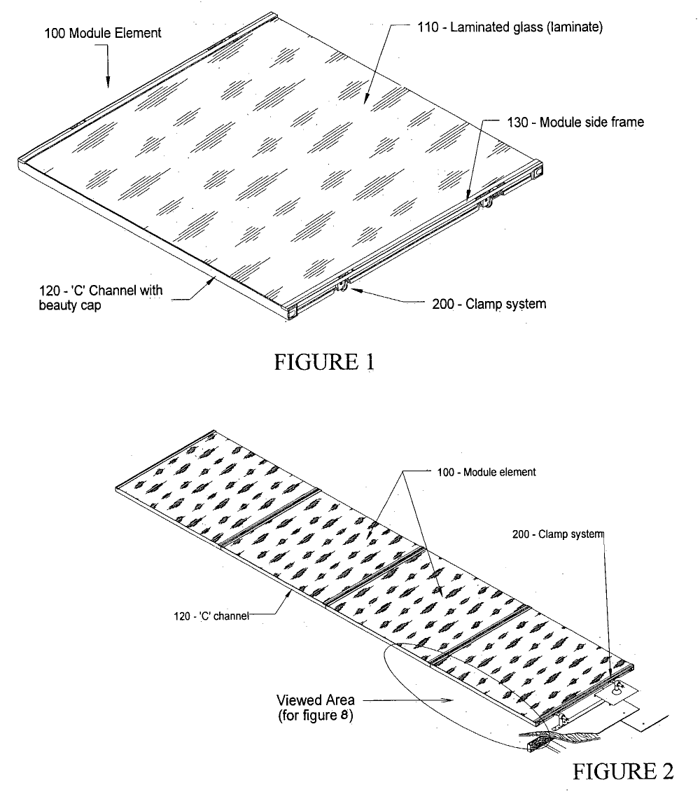

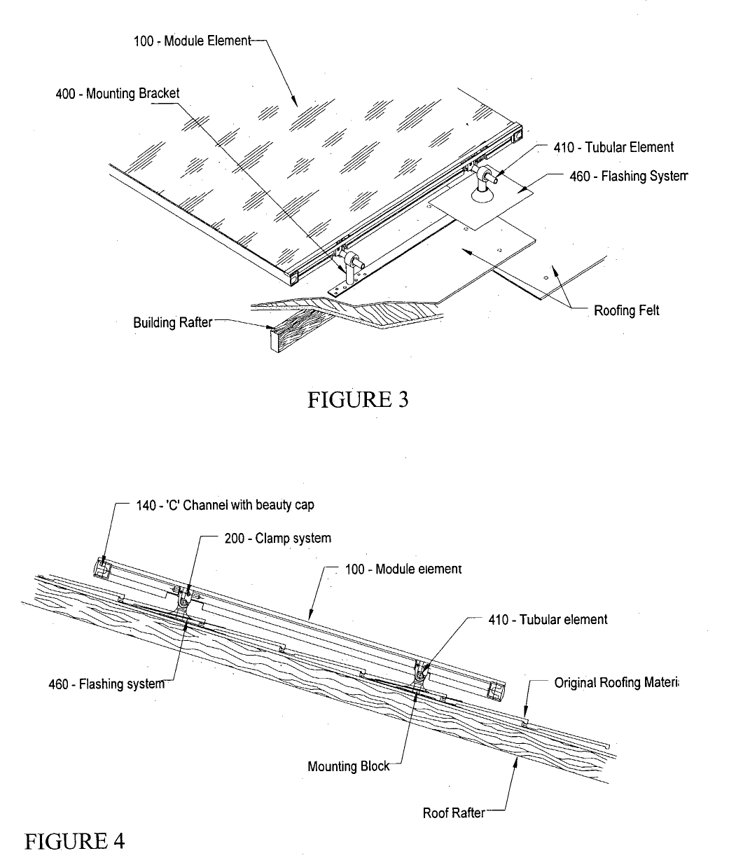

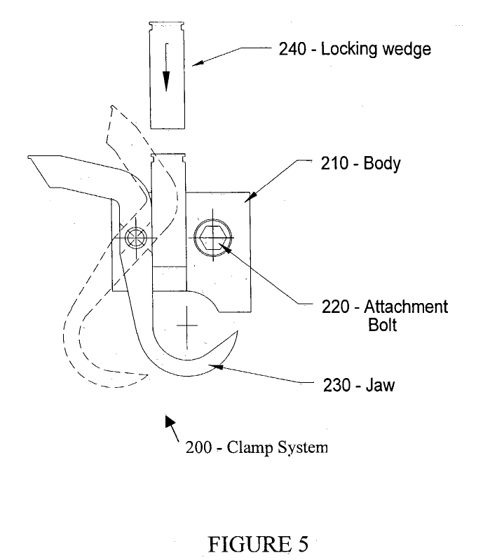

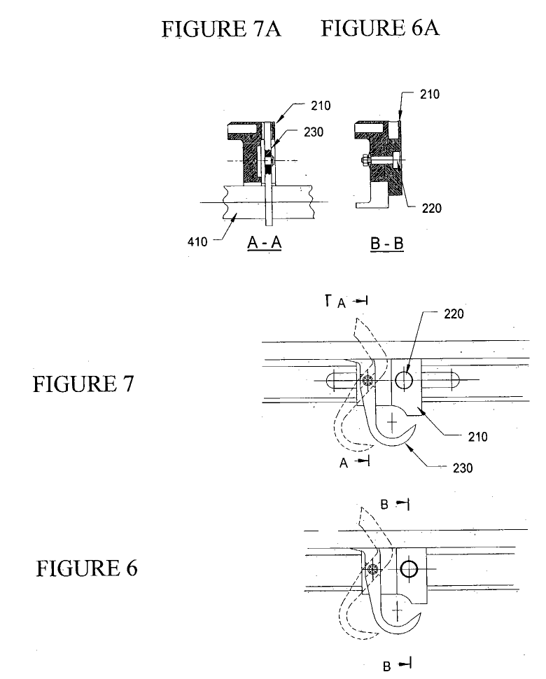

As illustrated in FIGS. 1-9, a photovoltaic module 100 includes a clamping arrangement clamp system 200 that cooperates with tubular elements 410, e.g., piping, to securely mount a module element 100. Referring particularly to FIGS. 5-7A, the clamps include two jaws 230 that are relatively pivotal with respect to one another. In an expanded configuration of the jaws 230, the tubular element 410 is received; and in a contracted configuration of the jaws, the tubular element is generally enclosed within the jaws. A locking wedge 240 can be used to maintain the jaws 230 in the contracted configuration. There are two types of clamp systems 200: fixed (FIGS. 6 and 6A) and movable (FIGS. 7 and 7A) with respect to the module element. In contrast to the fixed clamp, the movable clamp can be slid in a slot on the edge of the photovoltaic module 100. Preferably, the slot extends along a perpendicular axis with respect to the tubular element 410 so as to accommodate some variations in the spacing or parallelism of the tubular elements. The tubular elements 410 are attached to the mounting bracket 400, which is attached to the installation surface. In case the mounting brackets 400 are installed on a tilted roofing surface the mounting bracket will be covered with a flashing system 460 to prevent any integrity damage to the installation surface, e.g. roof According to the present invention, the clamp system 200 precludes separating the photovoltaic module 100 from the tubular elements 410, i.e., prevents non-coaxial movement of the photovoltaic module 100 relative to the tubular elements. However, if desired, the clamp system 200 can permit coaxial movement, i.e., sliding, of individual photovoltaic modules 100 along the tubular elements 410.

The clamp system 200 allows a panel element 100 to be securely attached to tubular elements 410, e.g., pipes, where the tubular elements 410 will determine the direction and alignment of the panel elements. The system will be accessible from the visible top of the panel elements 100 and provide an easy assembly or disassembly using only human hand force.

According to preferred embodiments, the clamp system directs forces applied on the panel element 100 to the tubular element 410 structures, and provides the installer with an easy, secure and safe installation of the panel elements.

The clamp system 200 can be assembled with 4 main parts: a body 210, an attachment bolt 220, a jaw 230, and a locking wedge 240. The body 210 supports all elements of the clamp. The body 210 may slide in a channel shape profile located on the side frame 130 of the panel element 100. The attachment bolt 220 is used to attach and secure the clamp to the side frame 130. The jaw 230 includes an operating end shaped to wrap around the tubular element 410 and a handling end that provides easy handling from above the top surface of the panel element 100. The locking wedge 240 is used to secure the jaw 230 from opening. According to a preferred embodiment of the present invention, and with particular reference to FIG. 5, the locking wedge 240 can include a body that is inserted between the body 210 and the jaw 230 to block movement of the jaw 230 from the arrangement shown in solid line to the arrangement shown in broken line, e.g., to prevent movement of the jaw 230 relative to the body 210 that would release the photovoltaic module 100 from the tubular element 410.

All clamps 200 can be movable. Preferably, the bottom clamp is mounted on the panel 100 approximately one-quarter of the distance from the bottom edge to minimize snow load stresses on the module 100. Preferably, these stresses will be distributed evenly. The moving clamps 200 can help align a photovoltaic module element 100 inasmuch as the two mounting tubular elements 410 may not be aligned relative to each other, e.g., the tubular elements may not be parallel to one another. Further, the modules 100 may need additional alignment relative to each other and other objects on the mounting surface. The clamp system 200 may also include resilient element biasing the jaw 230 relative to the body. According to a preferred embodiment of the present invention, a torsion spring could be used to bias the jaw 230 toward a clamping arrangement, e.g., the solid line depiction shown in FIG. 5. This system can be used with any application that requires a panel element, e.g., a panel, to be mounted on tubular elements or a pipe-like support system.

Referring to FIG. 2, a preferred array is shown that includes four modules elements 100 that are mounted using the clamping system 200. The array of module elements 100 can be arranged either horizontally or vertically: the modules can each have ‘C’ channels 120 that are aligned so as to provide a wire raceway that runs the lengths of the module array, as shown in FIG. 2, or there can be a space from one row to another row, in which a liquid tight conduit 325 can be used to connect the ‘C’ channel. After the wiring is completed, a cap 140 is installed to enclose the ‘C’ channel wire raceway.

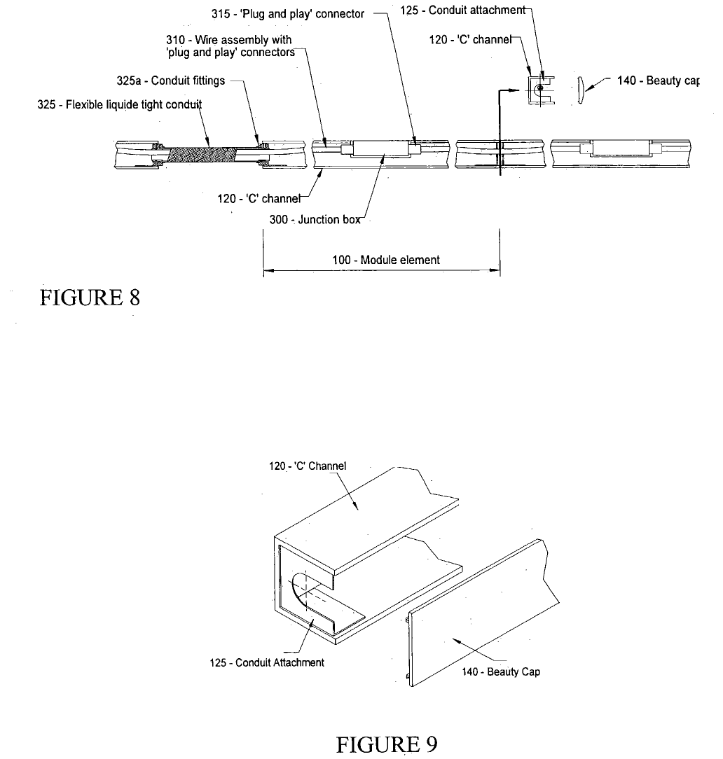

Referring particularly to FIGS. 8 and 9, the arrangement includes “C” shaped channels, ‘C’ channel 120, running along at least one an edge of each module. Near the ends of the channels, a bulkhead type formation can provide an attachment point for a wire-protecting sheath, e.g., conduit 125. At approximately the midpoint of the chase, a junction box 300 can be provided for enclosing the electrical connections. After making all required electrical connections, a cap 140 can be installed, to enclose the channels and thereby prevent severe environmental conditions from adversely affecting the wiring running in the ‘C’ channel.

According to preferred embodiments of the present invention, all cables will run in the ‘C’ channel 120. If exposed cables are necessary a flexible liquid tight conduit can be sleeved over the cables and attached to the module elements 100 conduit attachments 125. After installation the caps 140 will cover the ‘C’ channel 120 and will provide an aesthetically pleasing appearance and protect the cables. The ‘C’ channel 120 is used for a wire raceway.

The ‘C’ channels 120 are located on opposite ends of each module, for example top and bottom, as shown in FIG. 1, or left and right such that the rows of modules can run horizontally or vertically. The ‘C’ channels 120 also add strength to the ends of the modules. Preferably, the module is glass 110 and the ‘C’ channels 120 add structure and strength to the module ends. The C-channels 120 can be located on the underside allowing the top glass 110 to be frameless. Thus, modules according to a preferred embodiment do not have ends that could interfere with self-cleaning of the module elements 100.

Preferably, modules will be placed close to each other and the wire assembly 310 will be pre-assembled with some extra length. Also available will be jumper wires or extension wires of various lengths. Some runs will require conduit to be connected to the raceways—this can be provided as a pre-assembled unit or as plug ‘ends’. Modules will be placed in rows above each other; the modules can be connected from row to row using a flexible liquid tight conduit and pre-assembled wire assembly 310.

A cap 140 can be placed across the open side of the ‘C’ channel 120. In addition to providing an aesthetically pleasing appearance, the caps can provide safety for the wires, e.g., prevent the wires within the channel from being cut, eliminate direct sunlight and thus UV attack on the wires, provide some protection from the elements, e.g., snow, ice, rain, dirt and branches, and provide safety so no one can access the system without removing the cap.

Preferring additional to. FIG. 2, a ‘C’ channel 120 runs under the upper and lower module edge, with the open side facing outwards. The function of the channel is to accommodate and protect the wiring system and to facilitate speed of assembly. The ‘C’ channel can have a milled opening 305, preferably at a central location, to accommodate a module junction box 300, e.g., as shown in FIG. 8. The junction box 300 can be set into the ‘C’ channel 120 to plug wires into the edge of the junction box 300 or the end of the junction box 300.

After making all required electrical connections, a cover or cap 140 can be installed to enclose the ‘C’ channels 120 and thereby prevent severe environmental conditions from adversely affecting the wiring running in the ‘C’ channel 120. The cap 140 can be plastic and can clip over the open side of the ‘C’ channel 120. The cap 140 can provide protection for the wire assembly 310, the plug connections 315, and the junction box 300. The cap 140 can also give a finishing touch to the module 100 and system.

A conduit attachment 125 can be welded to the ends of the module elements 100 ‘C’ channel 120. Preferably, a 1″ hole/slot will be machined in this conduit attachment 125 plate to act as the mounting bracket for electrical conduit 325. A conventional 1″ conduit fitting 325a can be used to attach the conduit 325 to the conduit attachment 125. The 1″ liquid-tight, flexible conduit 325 can be a conventional non-metallic liquid tight conduit. Any exposed part of the wiring assembly 310 will be protected by the conduit 325.

A number of advantages are achieved according to the present invention. These advantages include individual photovoltaic modules being readily and simply clamped into place on a system of roughly positioned tubes, e.g., pipes, and that the entire clamping (and optional clamp locking) operation can be performed from the topside of the photovoltaic modules. Moreover, the clamping operations are performed without tools or additional parts, e.g., screws or nuts that are readily lost. Thus, advantages of the system include reducing installation and servicing time, and improving safety by virtue of minimizing the time spent in potentially dangerous situations, such as on a roof working with photovoltaic modules that are active (when solar energy is available to be converted to electricity).

Another advantage that is achieved is that this system enables each photovoltaic module to be mounted and electrically connected separately. As opposed to known systems, only two steps are required to install a photovoltaic module according to the present invention: locate the photovoltaic module in its final location and then make the necessary electrically connections.

Another advantage that is achieved is that the ‘C’ shaped channel according to the present invention provides a convenient, safe and aesthetically pleasing wire raceway, as well as provides reinforcement to the photovoltaic module. Further, the ‘C’ shaped channel provides a smooth continuation of the photovoltaic module's topside, and therefore does not interfere with the photovoltaic module's ability to be “self cleaning.”

Another advantage that is achieved is that, by virtue of there being more than one junction box provided on a photovoltaic module, there are additional options for positioning photovoltaic modules with respect to one another, and then simplifying the electrical connections between the photovoltaic modules.

While the present invention has been disclosed with reference to certain preferred embodiments, numerous modifications, alterations, and changes to the described embodiments are possible without departing from the sphere and scope of the present invention, as defined in the appended claims. Accordingly, it is intended that the present invention not be limited to the described embodiments, but that it have the full scope defined by the language of the following claims, and equivalents thereof.

What is claimed is:

1. A system of mounting a photovoltaic module on a structure, the photovoltaic module including at least one photovoltaic cell converting solar energy to electricity and including a first module face receiving the solar energy and a second module face generally confronting the structure, the system comprising:
a first element adapted to be mounted with respect to the structure; and
a first clamp engaging the first element and adapted to secure the photovoltaic module with respect to the structure, the first clamp including:
a body adapted to be positioned with respect to the photovoltaic module; and
a jaw pivoting about a pivot axis between first and second configurations relative to the body, the first configuration permitting non-coaxial displacement with respect to the pivot axis by the first clamp relative to the first element, and the second configuration generally preventing non-coaxial displacement with respect to the pivot axis by the first clamp relative to the first element, the jaw including:
a handling end adapted to be operated from the first module face of the photovoltaic module; and
an operating end cooperating with the first element.

2. The system according to claim 1, wherein the body is adapted to be fixed with respect to the photovoltaic module.

3. The system according to claim 1, wherein the body is adapted to be variably positioned with respect to the photovoltaic module.

4. The system according to claim 1, wherein the second configuration of the jaw relative to the body prevents coaxial displacement along the pivot axis of the first clamp relative to the first element.

5. The system according to claim 1, wherein the first element comprises an elongated member extending along a mounting axis.

6. The system according to claim 5, wherein the first element comprises a bracket locating the elongated member with respect to the structure.

7. The system according to claim 5, wherein the first element comprises a tube.

8. The system according to claim 5, wherein the body comprises a first surface cooperating with the first element and the operating end comprises a second surface cooperating with the first element, and the second configuration of the jaw relative to the body comprises the first and second surfaces extending about a majority of the mounting axis.

9. The system according to claim 1, further comprising:
a lock preventing the first clamp from being reconfigured from the second configuration to the first configuration, the lock being adapted to be operated from the first module face of the photovoltaic module.

10. The system according to claim 9, wherein the lock comprises a wedge contiguously interposed between the body and the jaw.

11. The system according to claim 10, wherein the wedge is contiguously interposed between the body and the handling end of the jaw.

12. The system according to claim 1, further comprising:
a resilient element biasing the jaw toward the second configuration

13. The system according to claim 1, further comprising:
a second element adapted to be mounted with respect to the structure; and
a second clamp engaging the second element and adapted to secure the photovoltaic module with respect to the structure.

14. The system according to claim 13, wherein the second element extends parallel to the first element, and the second clamp is spaced from the first clamp.

15. The system according to claim 1, further comprising:
a chase extending along a chase axis and adapted to be secured to the photovoltaic module, the chase including an opening extending parallel to the chase axis; and
a cap extending along the chase axis and being engageable with the chase, a first arrangement of the cap with respect to the chase providing access through the opening and a second arrangement of the cap occluding the opening.

16. The system according to claim 15, wherein the chase defines a wire raceway adapted to shield wires electrically interconnecting the photovoltaic module.

17. The system according to claim 15, wherein the chase comprises a generally C-shaped cross-section orthogonal to the chase axis, and the cap comprises a plate closing the C-shaped cross-section.

18. The system according to claim 17, wherein the chase comprises an attachment plate partially occluding an axial end of the chase.

19. The system according to claim 18, wherein the attachment plate provides a mechanical coupling for a wiring conduit.

20. An apparatus for mounting a photovoltaic module on a tube, the photovoltaic module including at least one photovoltaic cell converting solar energy to electricity and including a first module face receiving the solar energy and a second module face generally confronting the structure, the apparatus comprising:
a body adapted to be positioned with respect to the photovoltaic module; and
a jaw pivoting about a pivot axis between first and second configurations relative to the body, the first configuration permitting non-coaxial displacement with respect to the pivot axis by the first clamp relative to the tube, and the second configuration generally preventing non-coaxial displacement with respect to the pivot axis by the first clamp relative to the tube, the jaw including:
a handling end adapted to be operated from the first module face of the photovoltaic module; and
an operating end adapted to cooperate with the tube.

21. An apparatus for interconnecting a photovoltaic module, the photovoltaic module including at least one photovoltaic cell converting solar energy to electricity and including a first module face receiving the solar energy, a second module face generally confronting the structure, and an edge extending between the first and second module faces, the apparatus comprising:
a wire raceway extending along an axis and adapted to be secured to the edge of the photovoltaic module, the wire raceway including a generally C-shaped cross-section orthogonal to the axis and including an opening extending parallel to the axis;
a cap extending along the axis and being engageable with the wire raceway to close the C-shaped cross-section, a first arrangement of the cap with respect to the wire raceway providing access through the opening and a second arrangement of the cap with respect to the wire raceway occluding the opening;
an attachment plate partially occluding an axial end of the wire raceway, the attachment plate providing a mechanical coupling to a wiring conduit; and
at least three wires extending generally along the axis and adapted to electrically interconnect the photovoltaic module, the wires being shielded in the second arrangement of the cap with respect to the wire raceway.

22. A photovoltaic module for mounting on a structure via a mounting element, the photovoltaic module comprising:
first and second module faces and an edge that extends between the first and second module faces, the first module face receiving solar energy and the second module face being adapted to generally confront the structure;
a plurality of photovoltaic cells being commonly supported by a base, each of the photovoltaic cells converting the solar energy to electricity;
a manual attachment, the manual attachment being adapted to releasably secure the base with respect to the mounting element;
a junction box supported on the base and shielding electrical coupling to the plurality of photovoltaic cells; and
a wire raceway extending from the junction box along the edge.

23. The photovoltaic module according to claim 22, wherein the manual attachment comprises a clamp including a body and a jaw, the body being positioned along the edge, and the jaw pivoting about a pivot axis between first and second configurations relative to the body, the first configuration permitting displacement of the body from the mounting element, and the second configuration generally preventing displacement of the body from the mounting element;

24. The photovoltaic module according to claim 23, wherein the jaw comprises handling and operating ends, the handling end being operated solely from the first module face, and the operating end cooperating at the second module face with the mounting element.

25. The photovoltaic module according to claim 23, wherein the wire raceway includes a channel having a generally C-shaped cross-section and a cap being engageable with the channel to close the C-shaped cross-section.

26. A method of mounting a photovoltaic module on a support structure, the photovoltaic module including at least one photovoltaic cell converting solar energy to electricity and including a first module face receiving the solar energy, a second module face generally confronting the support structure, and an edge extending between the first and second module faces, the method comprising:
positioning the photovoltaic module with respect to the support structure; and securing without tools the photovoltaic module to the support structure.

27. The method according to claim 26, wherein the securing comprises clamping the photovoltaic module with respect to the structure, the clamping consisting essentially of operating a clamp from the first module face of the photovoltaic module.

28. The method according to claim 26, further comprising:
interconnecting electrically the photovoltaic module, the interconnecting occurring within a wire raceway having a generally C-shaped cross-section and being secured to the edge of the photovoltaic module.

29. The method according to claim 28, further comprising:
closing the C-shaped cross-section with a cap, the closing including shielding at least three wires extending within the wire raceway.
